(19) United States
(12) Patent Application Publication
(10) Pub. No.: US 2010/0122131 A1
(43) Pub. Date: May 13, 2010

(54) SEMICONDUCTOR MEMORY DEVICE AND TESTING METHOD THEREFOR

(75) Inventor: YOSHIRO RIHO, TOKYO (JP)

Correspondence Address: YOUNG & THOMPSON, 209 Madison Street, Suite 500, Alexandria, VA, 22314, US

(73) Assignee: ELPIDA MEMORY, INC., TOKYO (JP)

(21) Appl. No.: 12/616,871

(22) Filed: Nov. 12, 2009

(30) Foreign Application Priority Data
Nov. 11, 2008 (JP) 2008-289030

(51) Int. Cl. G11C 29/44; G11C 5/14; G06F 11/22

(52) U.S. Cl. 714/721; 365/189.09; 365/201; 714/E11.145

(57) ABSTRACT

A semiconductor memory device comprises a plate voltage generating circuit that generates a plate voltage supplied to a memory cell array and a plate voltage supply terminal that supplies a plate voltage from the outside. A first switching circuit is provided to switch the supply of the plate voltage between the supply from the plate voltage generating circuit and the supply from the outside through the plate voltage supply terminal.

This application is based upon and claims the benefit of priority from Japanese Patent Application No. 2008-289030, filed Nov. 11, 2008, the disclosure of which is incorporated herein in its entirety by reference.

### BACKGROUND OF THE INVENTION

1. Field of the Invention

The present invention relates to a semiconductor memory device and a testing method therefor.

2. Description of Related Art

In manufacture of a semiconductor memory device, it is usual practice that a data writing test is conducted on memory cells while they are still on a wafer in order to detect defective cells. Cell H test and cell L test are known as such data writing test. The cell H test is a test conducted by writing a voltage V_{ary}, or a high level into memory cells, whereas the cell L test is a test conducted by writing 0 V, or a low level into memory cells.

FIG. 1 is a flowchart showing an example of the cell H test applied to a semiconductor memory device.

As shown in FIG. 1, a cell H write operation of all the bits is performed in step S91, self-refresh entry is performed in step S92, the data is held, self-refresh exit is performed in step S93, a cell H read operation of all the bits is performed in step S94, and then a fail address (defective memory cell address) is extracted and a remedy determination is made in step S95.

In the above-mentioned cell H testing method, the setting of the data holding time (pose time) during the test is designed so as to be changeable to 200 ms and 300 ms relative to the normal data holding time of 100 ms in view of the memory cell data amount which is found during the assembly process and during the use in the market. However, this method is not effective enough to cope with the deterioration or defect of the memory cell data, and is not capable of avoiding the problem of prolonged testing time.

In the above-mentioned cell L testing method, the initial set value of plate voltage V_{PLT} is set to a value about twice as large as the design value in view of deterioration of a cell capacity film during the assembly process. However, this method is not effective enough to test breakdown of memory cell data caused by the deterioration of the cell capacity film.

A technique related to this type of tests is disclosed in Japanese Laid-Open Patent Publication No. 2000-173297 (Patent Document 1), in which the stress voltage applying time is shortened by designing the internally generated supply voltage to be variable arbitrarily.

### SUMMARY

The present invention seeks to solve one or more of the above problems, or to improve upon those problems at least in part.

In one embodiment, there is provided a semiconductor memory device that comprises a plate voltage generating circuit that generates a plate voltage supplied to a memory cell array, a plate voltage supply terminal that supplies a plate voltage from the outside, and a first switching circuit that switches the supply of the plate voltage between the supply from the plate voltage generating circuit and the supply from the outside through the plate voltage supply terminal.

In another embodiment, there is provided a method of testing memory cells of a semiconductor memory device, which comprises, during a test, supplying a plate voltage from the outside and varying the value of the plate voltage so as to have a value corresponding to a predetermined proportion of a design value, and performing extraction of a defective memory cell address and remedy determination.

In the testing method according to the above embodiment, when a cell H test is conducted as the test, the plate voltage during a read operation applied externally is set to a value 0.9 and 0.8 times as high as that of the plate voltage during a write operation applied externally, so that the data amount of the memory cells is made substantially 0.9 and 0.8 time and, subsequently, the defective memory cell address is extracted and determination is made whether the defective memory cell is to be remedied or not. When a cell L test is conducted as the test, the plate voltage during a read operation applied externally is set to a value 1.1 and 1.2 times as high as that of the plate voltage during a write operation applied externally, so that the data amount of the memory cells is made substantially 0.9 and 0.8 times, and, subsequently, extraction of the defective memory cell address and remedy determination are performed.

According to the testing method of the above embodiment, measures can be taken against deterioration and defects of memory cell data without prolonging the testing time.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a flowchart showing an example of a cell H test applied to a semiconductor memory device;

FIG. 2 is a diagram showing a configuration of a principal part of a semiconductor memory device according to an embodiment of the present invention;

FIG. 3 is a schematic diagram of the memory cell array shown in FIG. 2;

FIG. 4 is a flowchart showing a first example of operation of the cell H test applied to the semiconductor memory device of FIG. 3;

FIG. 5 is a flowchart showing a second example of operation of the cell H test applied to the semiconductor memory device of FIG. 3;

FIG. 6 is a diagram showing waveform variation with time of the pad potential of the plate voltage (indicated by the thin solid lines) and of the in-chip potential of the plate voltage (indicated by the thick solid lines) in the flow of FIG. 5;

FIG. 7 is a flowchart showing a first example of operation of the cell L test applied to the semiconductor memory device of FIG. 3;

FIG. 8 is a flowchart showing a second example of operation of the cell L test applied to the semiconductor memory device of FIG. 3; and

FIG. 9 is a diagram showing waveform variation with time of the pad potential of the plate voltage (indicated by the thin solid lines) and of the in-chip potential of the plate voltage (indicated by the thick solid lines) in the flow of FIG. 8.

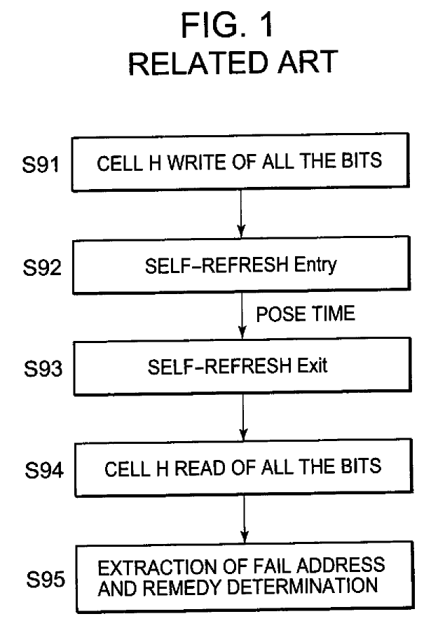

### DESCRIPTION OF EXEMPLARY EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

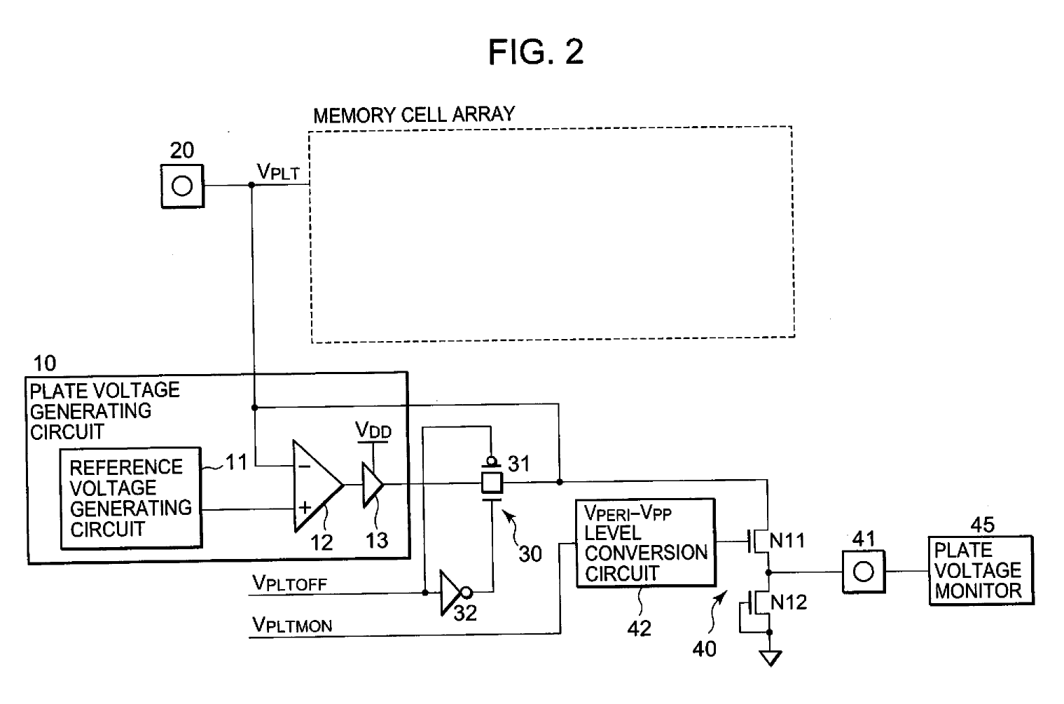

Referring to FIGS. 2 to 9, exemplary embodiments of the present invention will be described.

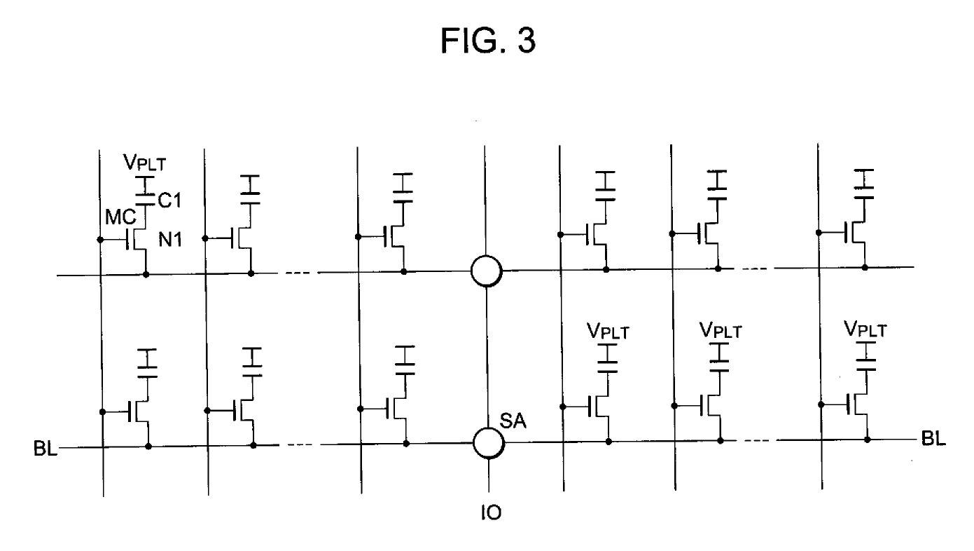

FIG. 2 shows a configuration of a principal part of a semiconductor memory device according to an embodiment of the invention, and FIG. 3 is a schematic diagram of the memory cell array shown in FIG. 2.

As shown in FIG. 3, the memory cell array is typically divided into a plurality of mats, and a plurality of memory cells MC are arranged in an array form in each of the mats. A sense amplifier region is provided between the adjacent mats, and a sense amplifier SA is provided on and connected to each bit line BL. The sense amplifier SA receives and outputs data through a data input/output line 10.

Each memory cell MC is composed of a transistor N1 and a capacitor C1. An end of the capacitor C1 is connected to a bit line BL through the transistor N1, so that a specific potential is applied thereto from the bit line BL. The other end of the capacitor C1 is fixed to a plate potential V_{PLT}. A word line WL is connected to the gate of the transistor N1.

As shown in FIG. 2, the semiconductor memory device according to the embodiment of the present invention comprises a plate voltage supply source which is composed of a plate voltage generating circuit 10, a plate voltage supply terminal 20, and a switching circuit (first switching circuit) 30 that switches between the plate voltage generated by the plate voltage generating circuit 10 and the external plate voltage supplied from the plate voltage supply terminal 20.

The plate voltage generating circuit 10 is composed of a reference voltage generating circuit 11, an operational amplifier 12, and a buffer 13, and generates a plate voltage V_{PLT}, using the external supply voltage V_{DD}, on the basis of a reference voltage generated by the reference voltage generating circuit 11.

The switching circuit 30 is composed of a transfer circuit 31 and an inverter 32, and performs switching operation according to a switching signal V_{PLTOFF}. Specifically, when the semiconductor memory device is in a normal operation mode, the switching signal V_{PLTOFF} is at a low level, and the plate voltage V_{PLT} is supplied from the plate voltage generating circuit 10 to the memory cell array through the transfer circuit 31. Normally, the plate voltage V_{PLT} is represented by (½) V_{ary}, in which V_{ary} is a voltage used in the memory cells. When the switching signal V_{PLTOFF} becomes a high level in the test mode described later, the plate voltage V_{PLT} from the plate voltage generating circuit 10 is blocked by the transfer circuit 31, and hence the memory cell array is not supplied with the plate voltage V_{PLT} from the plate voltage generating circuit 10, but instead with an external plate voltage from the plate voltage supply terminal 20.

Although the semiconductor memory device according to the shown embodiment has a plate voltage monitor circuit 40, but this is not an essential element. The plate voltage monitor circuit 40 includes transistors N11, N12 connected in series to the output of the transfer circuit 31 and a plate voltage monitor terminal 41 connected to the node of these transistors. The plate voltage monitor terminal 41 is connected to a plate voltage monitor 45. The configuration is such that the plate voltage monitor terminal 41 is supplied either with the plate voltage from the plate voltage generating circuit 10 via the switching circuit 30 and the transistor N11 serving as a switching element, or with the external plate voltage from the plate voltage supply terminal 20 via the transistor N11. The transistor N11 is turned on and off according to the level of a plate voltage monitor instruction signal V_{PLTMON} applied to the gate thereof.

More specifically, when the plate voltage monitor instruction signal V_{PLTMON} becomes a high level, the transistor N11 is turned on, whereby the plate voltage monitor terminal 41 is made conductive with the plate voltage generating circuit 10 or the plate voltage supply terminal 20, thereby enabling the monitoring of the plate voltage V_{PLT} through the plate voltage monitor terminal 41. In the shown embodiment, a V_{PERI}-V_{PP} level converting circuit 42 is connected to the gate of the transistor N11 to convert the high-level voltage V_{PERI} of the signal V_{PLTMON} to a high voltage level V_{PP}. This conversion is for the purpose of preventing the plate voltage V_{PLT} from being varied by the N-channel transistor N11. Therefore, the level converting circuit 42 is not necessary any more if a P-channel transistor is used in place of the N-channel transistor N11. In either case, the transistor N11 and the V_{PERI}-V_{PP} level converting circuit 42 together may be called a second switching circuit. The switching signal V_{PLTOFF} and the plate voltage monitor instruction signal V_{PLTMON} are output from a main control section (not shown) of the semiconductor memory device. Although the external plate voltage supplied to the plate voltage supply terminal 20 is supplied from the outside of the semiconductor memory device in this embodiment, it may be supplied from an internal power-supply circuit.

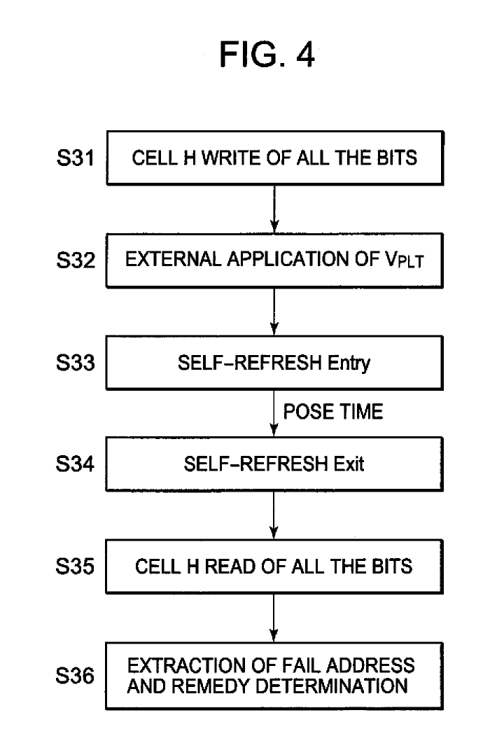

FIG. 4 is a flowchart showing a first example of operation of the cell H test applied to the semiconductor memory device of FIG. 3. The cell H test is a test conducted by activating a word line WL in the memory cell array shown in FIG. 3, and writing a voltage V_{ary} (at a high level) into a specific memory cell MC from the data input/output line IO via the bit line BL.

In the cell H test as shown in FIG. 4, a cell H write operation of all the bits is performed in step S31, the plate voltage V_{PLT} is externally applied (that is, the plate voltage is applied from the plate voltage supply terminal 20 as described above with reference to FIG. 2) in step S32, self-refresh entry is performed in step S33, the data is held (for a pose time of a fixed duration), self-refresh exit is performed in step S34, a cell H read operation of all the bits is performed in step S35, and then a fail address (defective memory cell address) is extracted and remedy determination is made in step S36. During the self-refresh operation, the word line WL is activated after setting the potential of the bit line BL to V_{BLP}, the data is amplified by the sense amplifier SA, and then the word line WL is deactivated. V_{BLP} denotes a voltage precharged to the bit line and is represented by the equation V_{BLP}=(½)V_{ary}.

In the process of testing the data holding time of cells at a high level on a wafer, as described above, the external plate voltage V_{PLT} from the plate voltage supply terminal 20 is set, by the operation of step S32, to values of 0.9 and 0.8 times the design value before reading out the data, so that the data amount in a memory cell is made substantially 0.9 and 0.8 times. After that, the remedy determination and assignment of memory cells for remedy are performed in step S36, whereby measures are taken against deterioration in the memory cell data amount during the assembly process or deterioration in the memory cell data amount during the use in the market.

The conversion equations for the amounts of read signals (cell capacity) can be represented as follows:

V_{sigH}=Cs/(Cs+Cb)×{V_{ary}-(V_{PLTw}-V_{PLTr})−V_{BLP}}

V_{sigL}=Cs/(Cs+Cb)×{Vₛₛ-(V_{PLTw}-V_{PLTr})−V_{BLP}}

where Cs denotes a memory cell capacity, Cb denotes a bit line capacity, Vₛₛ denotes a ground voltage, V_{PLTw} denotes a plate voltage level during a write operation, and V_{PLTr} denotes a plate voltage level during a read operation. These conversion equations are applicable also to other examples of operations described later.

According to this embodiment, as described above, the pose time between steps S33 and S34 is fixed, and thus effective measures can be taken against deterioration and defects of memory cell data without prolonging the testing time.

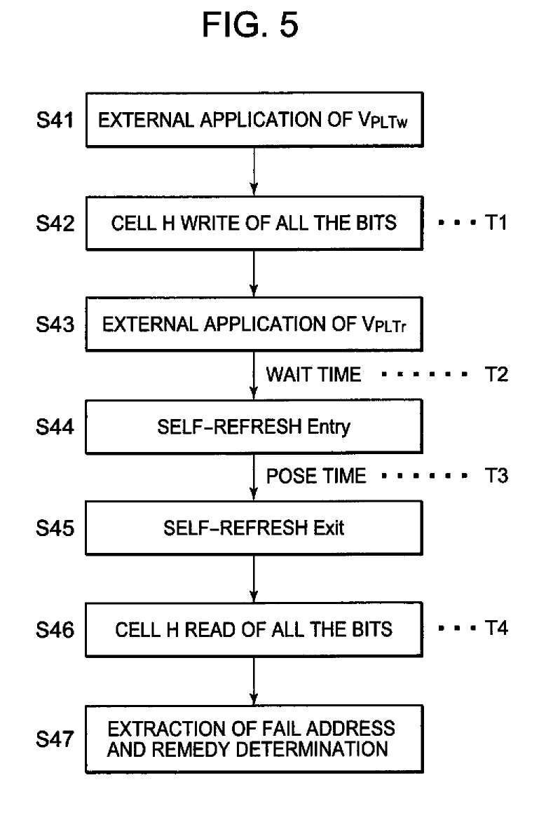

FIG. 5 is a flowchart showing a second example of operation of a cell H test applied to the semiconductor memory device of FIG. 3.

As shown in FIG. 5, a plate voltage V_{PLTw} during a write operation of a memory cell is applied externally (applied from the plate voltage supply terminal 20) in step S41, a cell H write operation of all the bits is performed in step S42, a plate voltage _{VPLTr} during a read operation is applied externally (applied from the plate voltage supply terminal 20) in step S43, a wait time T2 of a fixed duration is interposed between steps S43 and S44, self-refresh entry is performed in step S44, data is held for a pose time T3 of a fixed duration, self-refresh exit is performed in step S45, a cell H read operation of all the bits is performed in step S46, and then a fail address (defective memory cell address) is extracted and remedy determination is made in step S47.

In this example of operation as described above, the test is conducted by supplying the external plate voltage from the plate voltage supply terminal 20, and monitoring the variation in the plate voltage V_{PLT} by means of the plate voltage monitor 45 connected to the plate voltage monitor terminal 41. This makes it possible to start the cell H write and cell-refresh entry operations only after confirming that the plate voltage _{VPLTw} reaches its target value, and thus makes it possible to conduct a test more accurately than the example shown in FIG. 4.

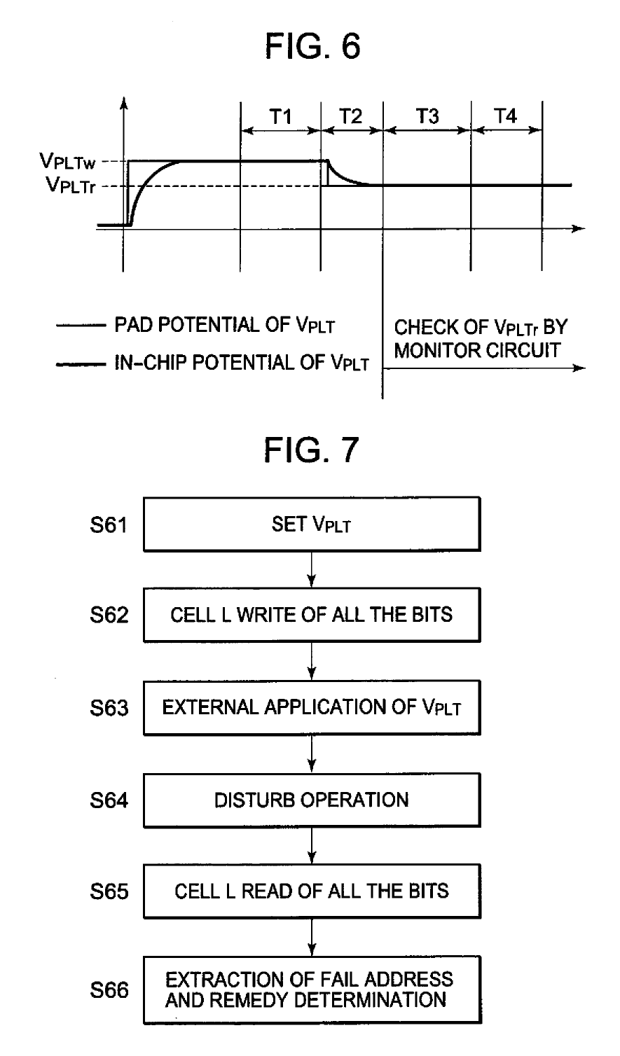

FIG. 6 shows waveform variation with time of the pad potential of the plate voltage V_{PLT} (indicated by the thin solid lines) and of the in-chip potential of the plate voltage V_{PLT} (indicated by the thick solid lines) in the flow of FIG. 5. After the plate voltage V_{PLTw} during a write operation is applied externally, the cell H write operation of all the bits of step 542 is performed in a period T1. Subsequently, after the plate voltage V_{PLTr} during a read operation is applied externally in step S43, the wait time is provided in a period T2 defined as after step S43 and before the potential is stabilized. The following period T3 is a time for data holding (pose) between steps S44 and S45 and the period T4 is a time for the cell H read operation of all the bits in step S46. After step S44, the plate voltage V_{PLTr} during a read operation is checked by the plate voltage monitor 45. The plate voltage V_{PLTr} during a read operation is set to values of 0.9 and 0.8 times the plate voltage V_{PLTw} during a write operation.

FIG. 7 is a flowchart showing a first example of operation of a cell L test applied to the semiconductor memory device of FIG. 3.

As shown in FIG. 7, the plate voltage V_{PLT} is set in step S61, a cell L write operation of all the bits is performed in step S62, an external plate voltage is applied from the plate voltage supply terminal 20 (applied externally) in step S63, a disturb operation is performed in step S64, a cell L read operation of all the bits is performed in step S65, and then a fail address is extracted and remedy determination is made in step S66.

In the process of testing cells at a low level on a wafer, as described above, the plate voltage V_{PLT} to be applied externally is set to values of 1.1 and 1.2 times the initial design value before reading the data so that the data amount of the memory cells is made substantially 0.9 and 0.8 times.

The remedy determination is made and assignment of memory cells for remedy is performed after the disturb operation and the cell L read operation of all the bits, whereby the problem is rectified of breakdown of memory cell data caused by the deterioration of the cell capacity film during the assembly process. This makes it possible to solve the deterioration problem in the memory cell data amount possibly occurring in the assembly process, in which the memory cell data amount is decreased by 10% or 20% due to deterioration of the cell capacity film, and thus the screening yield can be improved.

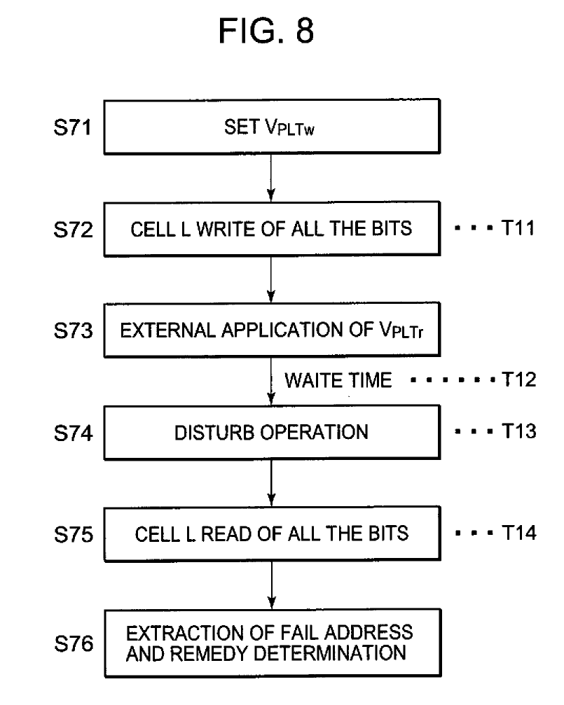

FIG. 8 is a flowchart showing a second example of operation of a cell L test applied to the semiconductor memory device of FIG. 3, and this example provides the same effects as those of the example described with reference to FIG. 5.

As shown in FIG. 8, a plate voltage V_{PLTw} during a write operation of memory cells is set in step S71, a cell L write operation of all the bits is performed in step S72, a plate voltage _{VPLTr} during a read operation is applied externally in step S73, wait time T12 is interposed between steps S73 and S74, a disturb operation is performed in step S74, a cell L read operation of all the bits is performed in step S75, and then a fail address is extracted and remedy determination is made in step S76. In this example as well, if the initial set value is 1.0 V, the plate voltage V_{PLT} to be applied externally is set to values obtained by adding 0.1 V and 0.2 V to the initial set value.

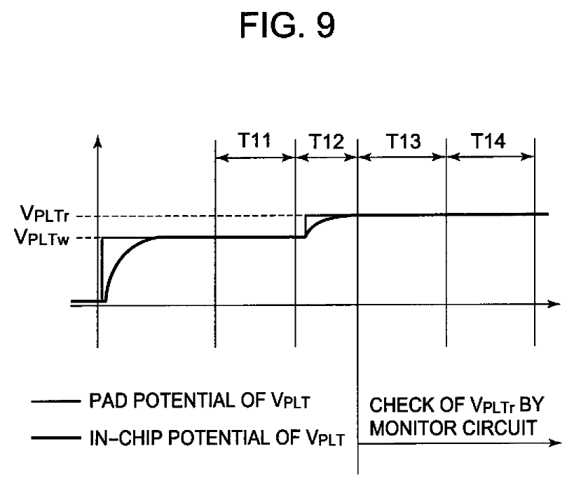

FIG. 9 shows waveform variation with time of the pad potential of the plate voltage V_{PLT} (indicated by the thin solid lines) and of the in-chip potential of the plate voltage V_{PLT} (indicated by the thick solid lines) in the flow of FIG. 8. After the plate voltage V_{PLTw} during a write operation is set, the cell H write operation of all the bits of step S72 is performed in a period T11. Subsequently, after the plate voltage V_{PLTr} during a read operation is applied externally in step S73, the wait time is provided in a period T12 defined as after step S73 and before the potential is stabilized. The following period T13 is a time for the disturb operation in step S74 and the period T14 is a time for the cell L read operation of all the bits in step S75. After step S74, the plate voltage V_{PLTr} during a read operation is checked by the plate voltage monitor 45. The plate voltage V_{PLTr} during a read operation is set to values of 1.1 and 1.2 times the initial set value (for example, set to the values obtained by adding 0.1 V and 0.2 V to the initial set value of 1.0 V).

According to the embodiment of the present invention described so far, the plate voltage V_{PLT} is set, in the process of testing data holding time of the cells at a high level on a wafer, to values of for example 0.9 and 0.8 times the design value before reading the data, whereby the data amount of the memory cells is made substantially 0.9 and 0.8 times. After that, the remedy determination is made and assignment of memory cells for remedy is performed, so that measures are taken against deterioration in the memory cell data amount during the assembly process or deterioration in the memory cell data amount during the use in the market.

For example, the present invention is able to cope with possible deterioration which decreases the memory cell data amount by 10% or 20% during the assembly process or during the use in the market, and thus provides advantageous effects of (1) improvement of the screening yield, (2) remedy for market defects, and (3) prevention of increase of the testing time since the data holding time in the test need not be as long as 200 ms or 300 ms, for example. Although the present invention has been described in conjunction with a few preferred embodiments thereof, the invention is not limited to the foregoing embodiments but various other variations and modifications will occur to those skilled in the art within the scope of the appended claims.

What is claimed is:

1. A semiconductor memory device comprising:
a plate voltage generating circuit that generates a plate voltage supplied to a memory cell array;
a plate voltage supply terminal that supplies a plate voltage from the outside; and
a first switching circuit that switches the supply of the plate voltage between the supply from the plate voltage generating circuit and the supply from the outside through the plate voltage supply terminal.

2. The semiconductor memory device as claimed in claim 1, further comprising, on the output side of the first switching circuit:
a plate voltage monitor terminal that supplies, to a plate voltage monitoring unit, the plate voltage supplied to the memory cell array; and
a second switching circuit that turns on and off the connection of the plate voltage to the plate voltage monitor terminal.

3. The semiconductor memory device as claimed in claim 1, wherein the first switching circuit switches the supply of the plate voltage between the supply from the plate voltage developing circuit and the supply from the outside through the plate voltage supply terminal, in response to a switching signal.

4. The semiconductor memory device as claimed in claim 2, wherein the first switching circuit switches the supply of the plate voltage between the supply from the plate voltage developing circuit and the supply from the outside through the plate voltage supply terminal, in response to a switching signal.

5. The semiconductor memory device as claimed in claim 1, wherein the second switching circuit turns on and off the connection of the plate voltage to the plate voltage monitor terminal, in response to a monitor instruction signal.

6. The semiconductor memory device as claimed in claim 2, wherein the second switching circuit turns on and off the connection of the plate voltage to the plate voltage monitor terminal, in response to a monitor instruction signal.

7. The semiconductor memory device as claimed in claim 3, wherein the second switching circuit turns on and off the connection of the plate voltage to the plate voltage monitor terminal, in response to a monitor instruction signal.

8. A method of testing memory cells of a semiconductor memory device, comprising:
during a test, supplying a plate voltage from the outside and varying the value of the plate voltage so as to have a value corresponding to a predetermined proportion of a design value; and
performing extraction of a defective memory cell address and remedy determination.

9. The testing method as claimed in claim 8, wherein when a cell H test is conducted as the test, the plate voltage during a read operation applied externally is set to a value 0.9 and 0.8 times as high as that of the plate voltage during a write operation applied externally, so that the data amount of the memory cells is thereby made substantially 0.9 and 0.8 times, and, subsequently, the extraction of a defective memory cell address and the remedy determination are performed.

10. The testing method as claimed in claim 8, wherein when a cell L test is conducted as the test, the plate voltage during a read operation applied externally is set to a value 1.1 and 1.2 times as high as that of the plate voltage during a write operation applied externally, so that the data amount of the memory cells is thereby made substantially 0.9 and 0.8 times, and, subsequently, the extraction of a defective memory cell address and the remedy determination are performed.
